(19) United States
(12) Patent Application Publication
(10) Pub. No.: US 2005/0166842 A1
(43) Pub. Date: Aug. 4, 2005

(54) Vapor deposition mask and organic EL display device manufacturing method

(75) Inventor: Yoshiaki Sakamoto, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 10/994,366

(22) Filed: Nov. 23, 2004

(30) Foreign Application Priority Data
Feb. 2, 2004 (JP) 2004-025596

(51) Int. Cl. C23C 16/00; B05D 5/06; B05D 5/12

(52) U.S. Cl. 118/721; 427/66

(57) ABSTRACT

A vapor deposition mask with high pattern accuracy particularly at vapor deposition openings is realized without changing the substrate structure. The vapor deposition mask includes a plate member, a first concave pattern provided at a first surface of the plate member, a second concave pattern provided at a second surface of the plate member on the opposite side of the plate member, and a through hole pattern provided at meeting or intersecting portions of the first concave pattern and the second concave pattern. The shape of the through hole pattern is arranged to be different from both that of the first concave pattern and that of the second concave pattern.

### BACKGROUND OF THE INVENTION

1. Field of the Invention

The present invention relates generally to a vapor deposition mask and an organic EL display device manufacturing method, and particularly to a vapor deposition mask having an opening portion with high pattern accuracy that is arranged to prevent vapor deposition patterning deviation.

2. Description of the Related Art

In recent years and continuing, much attention is being directed to organic EL (electroluminescence) display devices to be used in place of liquid crystal display devices in the field of mobile information terminal apparatuses such as mobile phones and mobile PCs.

An organic EL display device includes self-light-emitting pixels that develop electroluminescence on their own, and thereby, a backlight, which is an essential component of a transmissive liquid crystal display device, is not required in an organic EL display device. Also, since an organic EL display device does not use polarization, a wider perspective range may be realized in the organic EL display device compared to that of a liquid crystal display device.

Also, while a liquid crystal display device uses a color filter to realize color display, the organic EL display device uses organic color material with differing light emitting wavelengths to realize self emission of RGB light, and thereby, the organic EL display device does not require a color filter and is capable of realizing good color reproducing capabilities.

The display portion of such an organic EL display device, the low molecular organic EL element in particular, is formed through vacuum vapor deposition. In the case of producing a display with full-color display capabilities, each pixel within a screen area made up of numerous pixels is arranged to have color emitting layers corresponding to each of the colors R, G, and B.

Specifically, a metal mask is provided between a vapor deposition source and a deposition surface, and vapor deposition gas is passed through an opening of the metal mask corresponding to a predetermined pixel to form a light emitting layer made of an organic EL film on the deposition surface.

In such case, by arranging the metal mask to be in contact with the deposition surface, dimensional accuracy of the deposited film may be achieved. By repeating the above described process to form each of the R, G, and B light emitting layers, desirable light emitting pixels may be produced (e.g., see Japanese Laid-Open Patent Publication No. 2001-185350).

In this case, the deposition surface positioned on a substrate repeatedly comes into contact with the metal mask, and a metal mask to be used in a next process comes into contact with a deposition surface of a previous process so that the organic EL film formed in the previous process may be scratched or peeled, and damaged.

To counter such problems, a substrate structure is proposed in which a protruding structure, for example, is provided on the deposition surface side, that is, the substrate side, so as to prevent the metal mask and the deposition surface from coming into contact (e.g., see Japanese Laid-Open Patent Publication No. 8-315981).

Alternatively, a mask structure is proposed in which a plurality of column-shaped protrusions are provided at an edge portion of a mask opening of a metal mask for maintaining a predetermined distance between the metal mask and the deposition surface (e.g., see Japanese Laid-Open Patent No. 2003-123969).

However, in the case of providing protruding structures as described above, a process is required for forming such protruding structure on the substrate, which may lead to an increase in manufacturing costs of the substrate structure.

In another prior art example of providing a protruding structure on the mask side of a substrate structure, as is disclosed in Japanese Laid-Open Patent Publication No. 2003-123969, changes need not be made to the substrate structure. However, in this example, the R, G, and B color pixels are respectively arranged into columns to form a matrix pixel structure and the mask openings are simply arranged into a striped pattern so that maintaining the mask structure becomes difficult due to distortions and deviations and the color layers of the pixels may not be accurately created.

In a case of implementing a grid structure in which mask openings are separated according to each pixel, the corner portions of the openings are formed into R-shaped corners in an etching process, and as a result, the light emitting area of the pixel may be reduced so that the open area ratio may be decreased.

### SUMMARY OF THE INVENTION

Accordingly, it is an object of the present invention to provide a vapor deposition mask structure with high pattern accuracy particularly at mask openings without having to change the substrate structure.

According to an aspect of the present invention, a vapor deposition mask is provided, the mask including:
a plate member;
a first concave pattern provided at a first surface of the plate member;
a second concave pattern provided at a second surface of the plate member on the opposite side of the plate member; and
a through hole pattern provided at a meeting portion of the first concave pattern and the second concave pattern; wherein
a shape of the through hole pattern is arranged to be different from both that of the first concave pattern and that of the second concave pattern.

According to another aspect of the present invention, an organic EL display device manufacturing method is provided, the method including the steps of:
forming a set of electrode patterns for providing plural pixels on a deposition surface of a substrate; and
forming an organic light emitting layer corresponding to an electrode of the set of electrode patterns using a vapor deposition mask of the present invention.

### BRIEF DESCRIPTION OF THE DRAWINGS

FIG. 1 is a diagram showing a fundamental structure of a vapor deposition mask according to an embodiment of the present invention;

FIG. 2 is a diagram illustrating a manufacturing process of a vapor deposition mask according to a first embodiment of the present invention;

FIG. 3 is a diagram showing a structure of the vapor deposition mask according to the first embodiment;

FIG. 4 is a diagram illustrating a manufacturing process of an organic EL display device according to a second embodiment of the present invention;

FIG. 5 is a diagram illustrating the manufacturing process of the organic EL display device of the second embodiment continued from FIG. 4;

FIG. 6 is a perspective view showing the deposited states of light emitting layers according to the second embodiment;

FIG. 7 is a diagram illustrating the manufacturing process of the organic EL display device of the second embodiment continued from FIG. 6;

FIG. 8 is a diagram showing a structure of a vapor deposition mask according to a third embodiment of the present invention; and

FIG. 9 is a perspective view showing the deposited states of light emitting layers according to the third embodiment.

### DESCRIPTION OF THE PREFERRED EMBODIMENTS

In the following, preferred embodiments of the present invention are described with reference to the accompanying drawings.

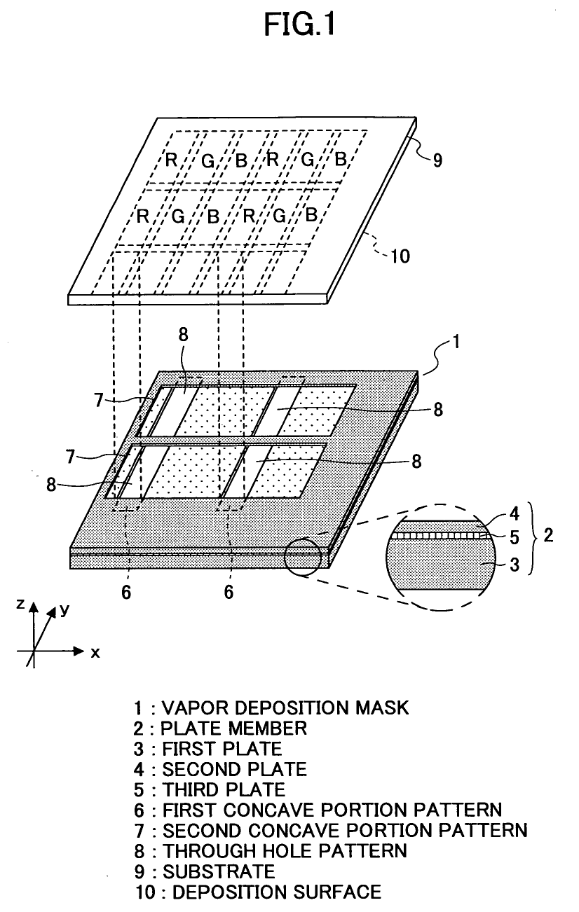

FIG. 1 illustrates a fundamental structure of a vapor deposition mask according to an embodiment of the present invention.

In this drawing, a vapor deposition mask 1 includes a plate member 2. On one side of this plate member 2 corresponding to a first surface, a first concave pattern 6 is provided. On the opposite side of the plate member 2 corresponding to a second surface, a second concave pattern 7 is provided. A through hole pattern 8 is provided at meeting or intersecting portions at which the first pattern 6 and the second pattern 7 meet or intersect in top plan view. The shape of this through hole pattern 8 is arranged to be different from both that of the first concave pattern 6 as well as that of the second concave pattern 7.

By arranging the meeting points of the first concave pattern 6 and the second concave pattern 7 to correspond to the through hole pattern 8, the corner portions of the holes (openings) 8 may be rectangular shaped rather than R-shaped so that a vapor deposition mask 1 with high pattern accuracy may be realized, and a large pixel area may be secured.

Particularly, in an embodiment in which at least one of the first concave pattern 6 and the second concave pattern 7 is arranged into a striped pattern, a suitable rectangular through hole pattern 8 that is well-adapted for pixel formation may be created.

Also, in another preferred embodiment, the plate member 2 is formed by laminating at least two types of materials having differing etching characteristics. In this way, the first concave pattern 6 and the second concave pattern 7 may be formed with high accuracy.

Particularly, the plate member 2 preferably includes a first plate 3 implementing the first concave pattern 6, a second plate 4 implementing the second concave pattern 7, and a third plate 5 provided in between the first plate 3 and the second plate 4 and having an etching characteristic that is different from that of the first plate 3 as well as that of the second plate 4. In this way, this third plate 5 may be used as an etching stopper so that the depths of the first concave pattern 6 and the second concave pattern 7 may be determined by the respective thicknesses of the first plate 3 and the second plate 4 rather than being controlled by the etching time.

Also, in an embodiment in which the second surface corresponds to a surface facing opposite a deposition surface 10 on which vapor deposition is conducted, the depth of the second concave pattern 7 is preferably arranged to be less than the first concave pattern 6. In this way, layer dimension accuracy of organic light emitting layers to be formed may be enhanced.

According to another embodiment, a set of electrode patterns for providing a plurality of pixels is formed, and organic light emitting layers corresponding to each individual electrode of the electrode patterns are formed through vapor deposition using the vapor deposition mask 1 as is described above. In this way, a high open area ratio may be achieved and an EL display device with high pattern accuracy may be realized.

In a preferred embodiment, areas of the vapor deposition mask 1 partitioning the second concave pattern 7 are arranged to be in contact with areas of the deposition surface 10 of a substrate 9 in between pixels or in between adjacent same-colored pixels of the deposition surface 10. In this way, even when the deposition layer 10 repeatedly comes into contact with the vapor deposition mask for each vapor deposition process corresponding to each of the light emitting colors, the vapor mask 1 may be prevented from coming into contact with the already-deposited pixels.

According to an aspect of the present invention, an arrangement may be realized in which the vapor deposition mask does not come into direct contact with the light emitting layers forming the pixels of a substrate deposition surface while securing the pattern accuracy of the vapor deposition mask. Thereby, damaging of elements through contact with the vapor deposition mask during an organic EL film deposition process may be avoided.

Also, according to another aspect of the present invention, structures for realizing features of the present invention are provided on the vapor deposition mask side so that additional production costs may not arise due to additional arrangements on the substrate side. In this way, production costs of the substrate structure may be maintained at a low cost. Also, according to another aspect of the present invention, individual holes are provided for each pixel as opening portions of the vapor deposition mask for forming the RGB color light emitting layers. In this way, rigidity of the vapor deposition mask may be increased thereby facilitating handling of the structure.

Particularly, it is noted that in the vapor deposition mask for forming the RGB color light emitting layers according to the prior art in which openings corresponding to same-colored pixel columns are arranged into a striped pattern, the periphery of the vapor deposition mask is welded while applying pressure thereon in order to maintain the pattern structure. However, there may be no need to conduct such tension welding according to an embodiment of the present invention, and thereby, a substrate structure may be produced at low cost.

According to an embodiment of the present invention, a vapor deposition mask for forming the respective RGB color light emitting elements has a three-layered structure including three mask material layers of which the middle layer corresponds to an etching stopper with etching characteristics that are different from those of the other two layers. On each of the front and back side surfaces of this three-layer structured mask, openings in a striped pattern are formed and portions at which the openings of the respective patterns meet are designated as through hole patterns through which vapor deposition gas passes.

Also, according to an organic EL display device manufacturing method corresponding to an embodiment of the present invention, upon conducting a light emitting layer forming vapor deposition process, the striped pattern on the vapor deposition mask surface that comes into contact with the deposition surface is arranged to correspond to the alignment of the RGB color layers, and the stripes between the openings of the pattern are arranged to come into contact with the areas in between the pixels of the substrate.

In the following, specific embodiments of the present invention are described with reference to the accompanying drawings.

### Embodiment 1

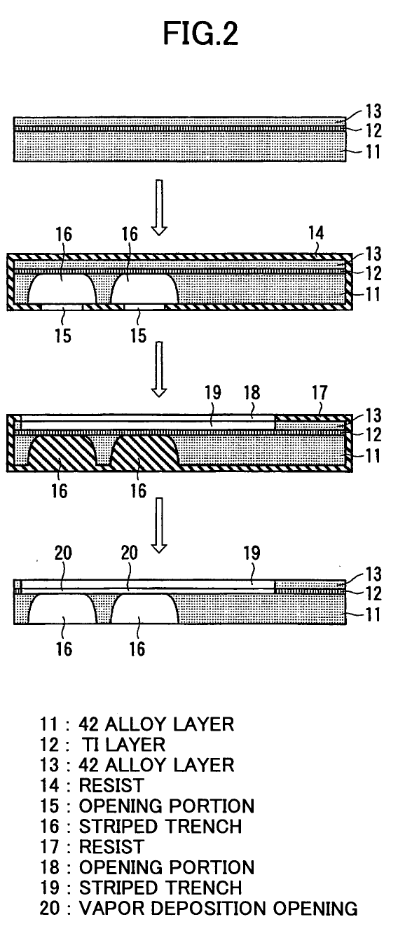

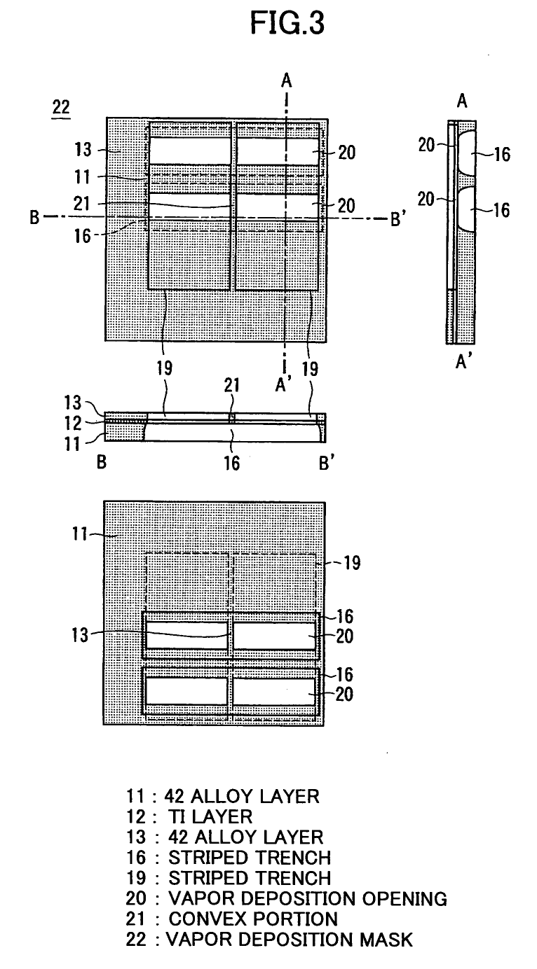

FIGS. 2 and 3 illustrate a vapor deposition mask according to a first embodiment of the present invention.

First, referring to FIG. 2, a metal plate member is formed by laminating on a 42 alloy (42 Ni—Fe) layer 11 with a thickness of 40 μm, for example, a Ti layer 12 with a thickness of 1 μm, for example, and then successively laminating a 42 alloy layer 13 with a thickness of 10 μm, for example, on the Ti layer 12.

Then, after a resist 14 is applied on the front and back surfaces of the metal plate member, plural opening portions 15 with a width of 100 μm are formed at a pitch of 360 μm, for example, to form a striped trench structure corresponding to a pattern of openings extending in the pixel column directions on the 42 alloy layer 11. Then, the resist 14 used to form the opening portions 15 is used as a mask to form striped trenches 16 through an etching process using a ferric chloride solution (50° C. [solution temperature], 47 Be [Baume density]).

In this example, the Ti layer 12 of the plate member for vapor deposition mask formation functions as an etching stopper. Accordingly, by conducting the etching process until the Ti layer 12 is exposed, the depths of the striped trenches 16 may correspond to the thickness of the 42 alloy layer 11 (e.g., 40 μm), the widths of the trenches 16 at the Ti layer 12 side may be approximately 100 μm, and the widths of the trenches 16 at the resist 14 side may be approximately 180 μm.

Then, after removing the resist 14, a new resist 17 is applied to the surfaces of the plate member and exposure and development processes are performed thereon. Specifically, plural opening portions 18 having a width of 300 μm, for example, are formed at a pitch of 360 μm, for example, to form a striped trench structure corresponding to a pattern of openings extending in the pixel row directions on the 42 alloy layer 13. Then, the resist 17 used to form the openings 18 is used as a mask to form striped trenches 19 through conducting an etching process using a ferric chloride solution (50° C. [solution temperature], 47 Be [Baume density]) until the Ti layer 12 is exposed.

Then, after removing the resist 17, the plate structure is immersed in a hydrofluoric solution to etch and remove the exposed Ti layer 12. In this way, perforated through holes as vapor deposition openings 20 are formed at the meeting or intersecting portions of the striped trenches 16 and the striped trenches 19 to realize a vapor deposition mask 22 for forming an R color light emitting layer.

FIG. 3 is a diagram showing the structure of the vapor deposition mask according to the first embodiment. As is shown in this drawing, a convex portion 21 is left in between the striped trenches 19 of the 42 alloy layer 13 at the deposition surface side, and this convex portion 21 is arranged to be in contact with the deposition substrate during vapor deposition in the light emitting layer formation process which is described below.

It is noted that the positioning of vapor deposition openings of a vapor deposition mask for one color may be shifted with respect to the positioning of vapor deposition openings of a vapor deposition mask for another color to form vapor deposition masks corresponding to different colors. For example, a vapor deposition mask for the G color light emitting layer and a vapor deposition mask for the B color light emitting layer may be formed by shifting the positioning of their vapor deposition openings by 120 μm and 240 μm, respectively, from the positioning of the vapor deposition openings 20 of the vapor deposition mask 22 for the R color layer.

Also, in the vapor deposition mask according to the first embodiment of the present invention, a three-layer laminated metal plate member including a middle Ti layer 12 as an etching stopper is used. With such an arrangement, the depth of trenches may be accurately controlled without having to accurately control the etching time. Also, the vapor deposition openings 20 are formed at the meeting or intersecting portions of the striped trenches 16 and the striped trenches 19 so that the corner portions of the vapor deposition openings 20 may be prevented from being R-shaped and the open area ratio may be increased compared to the grid pattern mask of the prior art.

### Embodiment 2

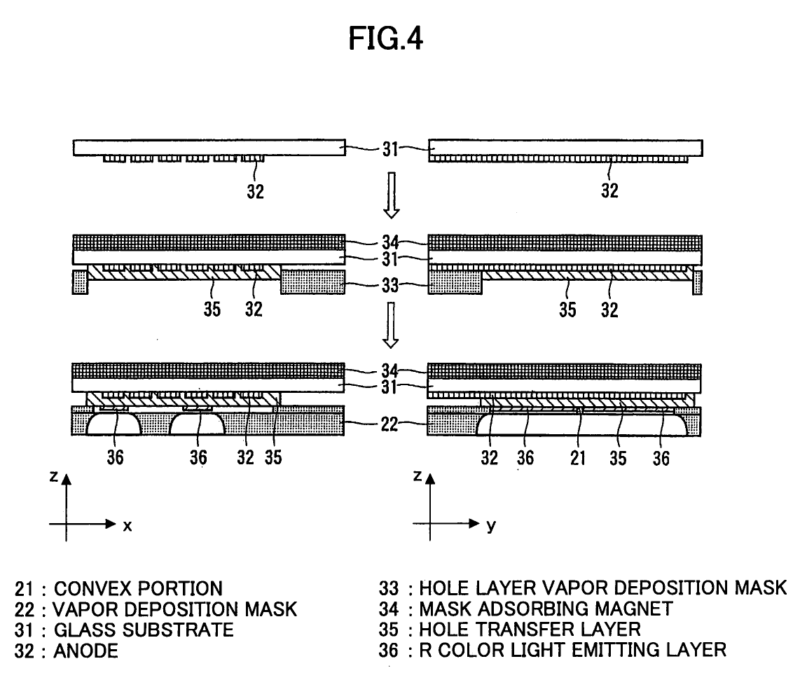

In the following, an organic EL display device manufacturing method according to a second embodiment of the present invention is described with reference to FIGS. 4 through 7. It is noted that in each of FIGS. 4, 5, and 7, the left side section corresponds to a cross-sectional view across line A-A′ of FIG. 3, and the right side section corresponds to a cross-sectional view across line B-B′ of FIG. 3.

First, referring to FIG. 4, an ITO film (not shown) having a thickness of 150 nm, for example, is deposited on a glass substrate 31 having a thickness of 0.7 mm, for example, after which anodes 32 having a width of 80 μm are formed at a pitch of 120 μm, for example, through a normal photo etching process.

In this example, the glass substrate 31 is preferably made of alkali-free glass, which has a thermal expansion coefficient that is close to that of the 42 alloy used for the vapor deposition mask.

Then, a hole layer vapor deposition mask 33 is positioned to the deposition surface of the substrate 31, while a mask adsorbing magnet 34 is positioned on the other side of the glass substrate 31 to adsorb the hole layer vapor deposition mask 33 so that it may be fixed to the deposition surface of the glass substrate 31. Then, a hole transfer layer 35 that may correspond to a 100 nm-thick α-NPD (naphthyl-diphenyl-diamine) layer, for example, is deposited on the deposition surface using a vacuum vapor deposition apparatus under a pressure of 10⁻⁵˜10⁻⁶ Pa.

It is noted that the hole transfer layer 35 is preferably formed evenly throughout the display surface.

Then, after the hole layer vapor deposition mask 33 is removed, a first vapor deposition mask corresponding to the R color vapor deposition mask 22, for example, is adsorbed by the mask adsorbing magnet 34 so that the convex portions 21 of the vapor deposition mask 22 may be held in contact with the surface of the hole transfer layer 35, after which an R color light emitting layer 36 having a thickness of 50 nm, for example, is formed using a vacuum vapor deposition apparatus under a pressure of 10⁻⁵˜10⁻⁶ Pa.

It is noted that for the R color light emitting layer 36, for example, an aluminum quinoline complex (Alq3) may be used as a host, and 1% DCJTB (4-dicyanomethylene-6-cp-julolidinostyryl-2-tert-buthyl-4H-pyran) may be used as a guest.

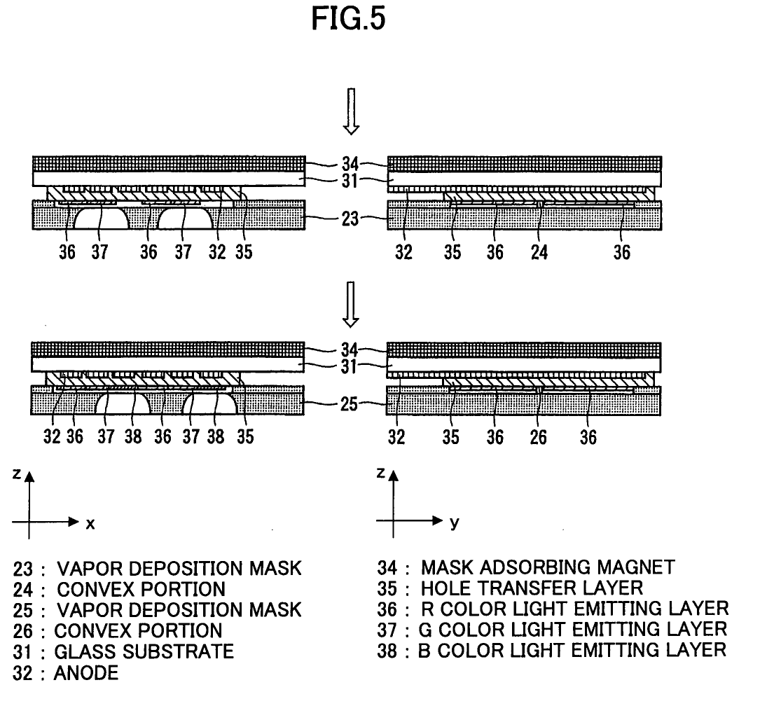

Next, referring to FIG. 5, after removing the vapor deposition mask 22, a second vapor deposition mask corresponding to a G color vapor deposition mask 23, for example, is adsorbed by the mask adsorbing magnet 34 so that the convex portions 24 thereof may be held in contact with the surface of the hole transfer layer 35, after which a G color light emitting layer 37 having a thickness of 50 nm, for example, is formed at a position shifted from the R color light emitting layer 36 by 120 μm using a vacuum vapor deposition apparatus under a pressure of 10⁻⁵˜10⁻⁶ Pa.

It is noted that for the G color light emitting layer 37, for example, an aluminum quinoline complex (Alq3) may be used as a host, and 1% dimethyl quinacridone may be used as a guest.

Then, after removing the vapor deposition mask 23, a third vapor deposition mask corresponding to a B color vapor deposition mask 25, for example, is adsorbed by the mask adsorbing magnet 34 so that the convex portions 26 thereof may be held in contact with the surface of the hole transfer layer 35, after which a B color light emitting layer 38 having a thickness of 50 nm, for example, is formed at a position shifted from the G color light emitting layer 37 by 120 μm using a vacuum vapor deposition apparatus under a pressure of 10⁻⁵˜10⁻⁶ Pa.

It is noted that for the B color light emitting layer 38, for example, 4,4′-bis(9-carbazolyl)-biphenyl (CBP) may be used as a host, and 10% 1,3,6,8-tetraphenyl-pyrene may be used as a guest.

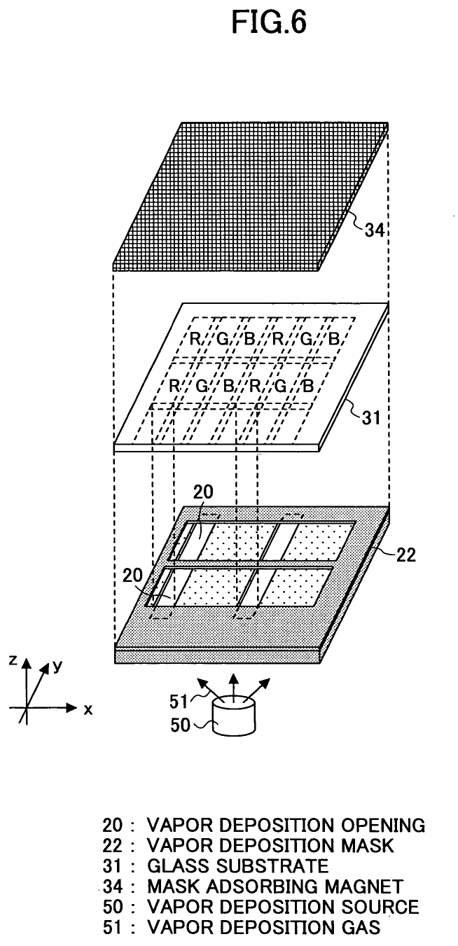

FIG. 6 is a perspective view showing the deposited states of the light emitting layers. As is described above, in forming the RGB color light emitting layers, the light emitting layer vapor deposition mask 22 is placed on the deposition surface of the glass substrate 31, and this mask 22 is adsorbed to the deposition surface of the glass substrate 31 by the mask adsorbing magnet 34 placed on the other side of the glass substrate 31. Then, a vapor deposition gas 51 corresponding to the color of the light emitting layer to be formed is generated from a vapor deposition source 50 positioned below the vapor deposition mask 22, and this gas 51 passes through the vapor deposition opening portions 20 provided at the vapor deposition mask 22 so that the RGB color light emitting layers are successively formed on the glass substrate 31.

In this embodiment, the surfaces of the vapor deposition masks 22, 23, and 25 on which the shallower striped trenches 19 are formed are arranged to correspond to the contact surfaces with the substrate so that the openings of the masks may be positioned close to the substrate deposition surface. In this way, vapor deposition patterning deviations may be prevented.

Also, in the present embodiment, contacting portions of the masks 22, 23, and 25 with the glass substrate 31 are arranged to correspond to the concave portions 21, 24, and 26 remaining on the thinner 42 alloy layer 13 side of the masks, and these concave portions 21, 24, and 26 are arranged to be positioned in between same-color pixels. In this way, the periphery portions of the vapor deposition openings 20 may be prevented from coming into direct contact with the light emitting layers, and light emitting layers that are already formed may be protected from damaging.

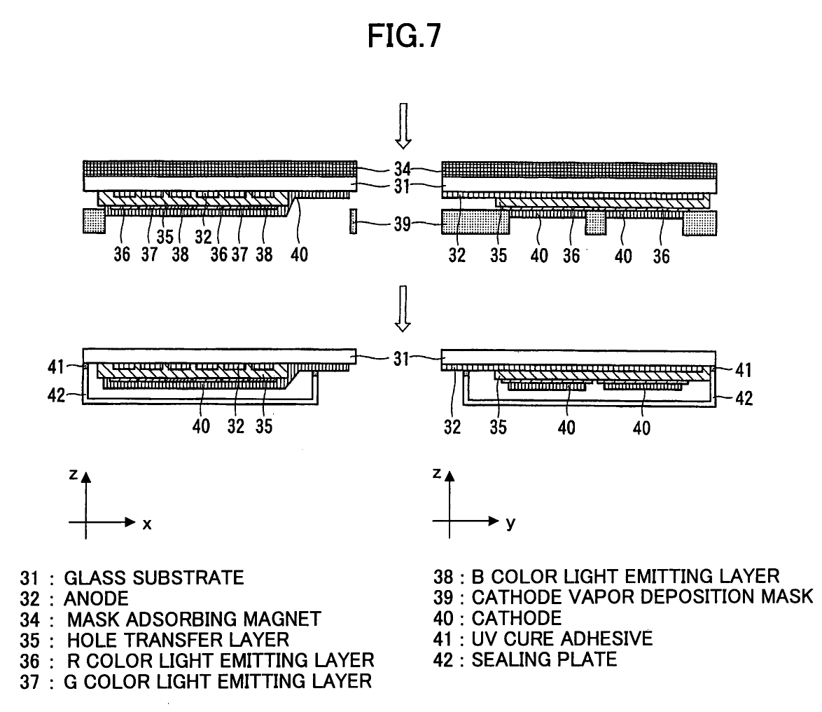

Then, referring to FIG. 7, after the vapor deposition mask 25 is removed, a cathode vapor deposition mask 39 is placed on the light emitting layers and is adsorbed by the mask adsorbing magnet 34 at the other side of the substrate 31 so as to be in contact with the light emitting layers. Then, striped cathodes 40 extending in an intersecting direction with respect to the anodes 32 are formed by depositing an Al—Li alloy film having a thickness of 100 nm, for example, in a vacuum vapor deposition process under a pressure of 10⁻⁵˜10⁻⁶ Pa.

Then, after removing the cathode vapor deposition mask 39, a sealing plate 42 that is made of glass is bonded to the substrate 31 using a UV cure adhesive 41 in a N₂ atmosphere under atmospheric pressure so as to protect the organic EL layers formed on the glass substrate 31 from external factors (e.g., moisture, oxygen, etc.) and prevent element degradation.

In this case, the wiring ends of the anodes 32 and cathodes 40 for inducing light emission of the pixels are arranged to be positioned outside the sealing plate 42.

In such an arrangement, the wiring ends of the anodes 32 and the cathodes 40 are connected to a drive circuit so that an image display may be obtained by controlling the light emission of the plural RGB color pixels within a screen using a progressive scan drive method (passive matrix drive).

Specifically, the anodes may be arranged to correspond to data lines and the cathode may be arranged to correspond to scan lines, and pixels at interesting points of these lines may emit light when a voltage is applied thereto from the anode side to the cathode side in a positive direction.

### Embodiment 3

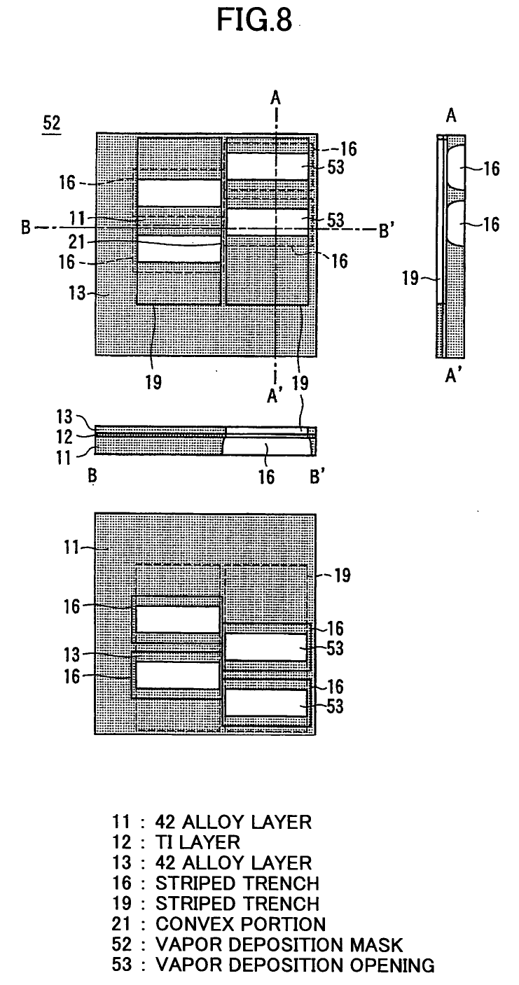

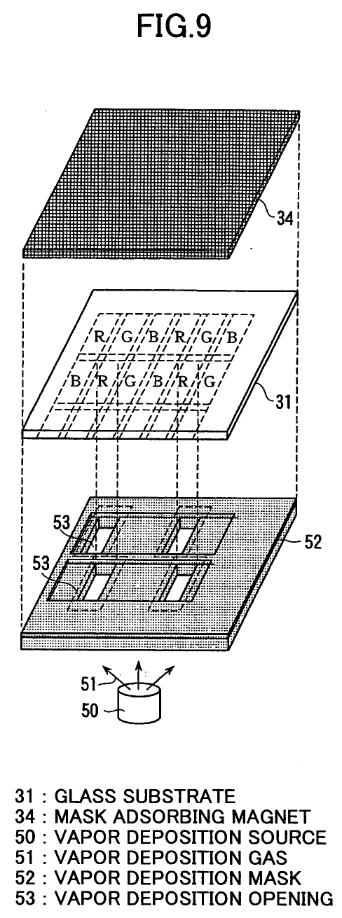

In the following, a vapor deposition mask according to a third embodiment of the present invention is described with reference to FIGS. 8 and 9. It is noted that the vapor deposition mask of this embodiment may be manufactured in a manner identical to that for manufacturing the vapor deposition mask according to the first embodiment, and thereby, descriptions of the manufacturing process for the vapor deposition mask of the present embodiment are omitted.

FIG. 8 is a diagram showing the structure of the vapor mask 52 according to the third embodiment in which the rows of perforated vapor deposition openings 53 are shifted from one another by a pitch corresponding to the dimension (width) of one color pixel.

FIG. 9 is a perspective diagram showing the deposited states of the light emitting layers. In forming the RGB color light emitting layers according to the present embodiment, a light emitting layer vapor deposition mask 52 is placed on the deposition surface side of a glass substrate 31, and this vapor deposition mask 52 is adsorbed to the deposition surface of the glass substrate 31 by a mask absorbing magnet 34 that is positioned on the other side of the glass substrate 31. Then, a vapor deposition gas 51 corresponding to the color of the light emitting layer to be formed is generated at a vapor deposition source 50 positioned under the vapor deposition mask 52, and this vapor deposition gas 51 is passed through the vapor deposition openings 53 of the vapor deposition mask 52 to form light emitting layers on the substrate 31.

According to this embodiment, a full-color display device having RGB color light emitting pixels arranged into a delta pattern as is shown in the drawing may be created.

It is noted that the above-described embodiments of the present invention are presented by way of example only, that is, the present invention is by no way limited by the specific conditions and features of the these embodiments. Rather, various changes and modifications may be made from these embodiments without departing from the scope of the present invention. For example, dimensions such as the widths, lengths, depths, and thicknesses of the elements of the present invention are not limited to the values indicated above.

Also, in the embodiments described above, the vapor deposition mask is created by forming a three-layer laminated metal plate structure, after which the front and back side outer 42 alloy layers are individually etched in separate processes. However, since a middle Ti layer is provided as an etching stopper, the opening patterns may also be formed on the front and back sides of the resist surface and etched in the same process.

Also, in the embodiments described above, the same material (i.e., 42 alloy) is used for the front and back outer layers of the vapor deposition mask. However, the present invention is not limited to such arrangement and magnetic materials with differing etching characteristics may be used for the outer layers of the vapor deposition mask.

It is noted that in such case, the middle layer such as the Ti layer acting as an etching stopper may not be required depending on the materials being used as the front and back side layers.

Also, in the above-described embodiments, the vapor deposition mask is arranged into a three-layer laminated metal plate structure. However, the present invention is not limited to such a laminated metal arrangement. Rather, the vapor deposition mask may also be made of a single metal material.

For example, desired patterns may be etched on both sides of a single metal material plate, and the portions at which the etching patterns of the respective sides meet or intersect may be arranged to correspond to through holes. In such case, the patterns on the respective sides of the single metal plate may be etched in separate processes, and the depth of the etching may be adjusted by controlling the etching rate and the etching time to form the through holes.

It is noted that even with a single metal material plate, etching of the patterns on the front and back sides of the metal plate may still be conducted simultaneously to form the through holes.

Also, in the embodiments described above, a major portion of the vapor deposition mask is made of a 42 alloy. However, the vapor deposition mask may also be made of an alloy of some other composition, and moreover, the vapor deposition mask may also be made of other types magnetic metal materials.

Also, in the embodiments described above, a magnet is used to fix the vapor deposition mask, and thereby, a major portion of the vapor deposition mask is made of a magnetic material. However, the vapor deposition mask may also be fixed through other non-magnetic means such as mechanical binding in which case the material of the vapor deposition mask does not necessarily have to be a magnetic material, and may also be a non-magnetic metal material or non-metallic material such as a ceramic material.

Also, in the second embodiment of the present invention, glass is used for the sealing plate. However, the material of the sealing plate is not limited to glass, and, for example, a metallic sealing plate or plastic sealing plate may be used instead.

Also, in the second embodiment, UV cure adhesive is used to bond the sealing plate so as to prevent element degradation from adhesive curing. However, the present invention is not limited to use of such adhesive and, for example, normal thermosetting adhesive may be used as well.

Also, the vapor deposition masks according to the above embodiments are described as being adapted for forming organic EL layers. However, the present invention is not limited to the formation of organic EL layers, and may be suitable for other various vapor deposition processes in which intricate rectangular patterns are used. For example, the present invention may also be used to form color filters of a liquid crystal display device through vapor deposition.

Also, in the embodiments described above, light emitting layers in three different colors, namely, colors R, G, and B, are alternatingly formed to create a full-color display. However, the present invention is not limited to a full-color display, and may also be used to create a display device with light emitting layers in two different colors, for example.

Also, it is noted that the hole transfer layer, the light emitting materials and the electrode materials mentioned with respect to the second embodiment are merely presented as examples, and other various hole types of transfer layers, light emitting materials and electrode materials may also be used.

The present application is based on and claims the benefit of the earlier filing date of Japanese Patent Application No.2004-025596 filed on Feb. 2, 2004, the entire contents of which are hereby incorporated by reference.

1. A vapor deposition mask, comprising:
a plate member;
a first concave pattern provided at a first surface of the plate member;
a second concave pattern provided at a second surface of the plate member on the opposite side of the plate member; and
a through hole pattern provided at a meeting portion of the first concave pattern and the second concave pattern; wherein
a shape of the through hole pattern is arranged to be different from a shape of the first concave pattern and a shape of the second concave pattern.

2. The vapor deposition mask as claimed in claim 1, wherein at least one of the first concave pattern and the second concave pattern corresponds to a striped pattern.

3. The vapor deposition mask as claimed in claim 1, wherein the plate member is formed by at least two different types of materials having differing etching characteristics that are arranged into a laminated structure.

4. The vapor deposition mask as claimed in claim 1, wherein the plate member includes:
a first plate at which the first concave pattern is provided;
a second plate at which the second concave pattern is provided; and
a third plate provided between the first plate and the second plate and having an etching characteristic that is different from an etching characteristic of the first plate and an etching characteristic of the second plate.

5. The vapor deposition mask as claimed in claim 1, wherein:
the second surface corresponds to a surface facing opposite a deposition surface on which deposition surface a vapor deposition material is deposited; and
a depth of the second concave pattern is arranged to be shallower than the depth of the first concave pattern.

6. An organic EL display device manufacturing method, comprising the steps of:
forming a set of electrode patterns for providing a plurality of pixels on a deposition surface of a substrate; and
forming an organic light emitting layer corresponding to an electrode of the set of electrode patterns using a vapor deposition mask including a plate member, a first concave pattern provided at a first surface of the plate member, a second concave pattern provided at a second surface of the plate member on the opposite side of the plate member, and a through hole pattern provided at a meeting portion of the first concave pattern and the second concave pattern, wherein a shape of the through hole pattern is arranged to be different from a shape of the first concave pattern and a shape of the second concave pattern.

7. The organic EL display device manufacturing method as claimed in claim 6 further comprising arranging an area of the vapor deposition mask partitioning the second concave pattern to come into contact with an area of the vapor deposition surface of the substrate in between pixels or in between adjacent same-colored pixels of the deposition surface.

8. A method of making a vapor deposition mask, comprising:
forming first and second concave patterns at opposite sides of a plate member;
forming a through hole pattern at a meeting portion of the first and second concave patterns, the through hole pattern having a shape different from the shape of the first and second concave patterns.
